(19) United States
(12) Patent Application Publication
(10) Pub. No.: US 2007/0138493 A1
(43) Pub. Date: Jun. 21, 2007

(54) Light-receiving module

(75) Inventors: Kazumi Morimoto, Kyoto (JP); Nobuo Asada, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 10/587,158

(22) PCT Filed: Jan. 24, 2005
(86) PCT No.: PCT/JP05/00866

§ 371 Date: Jul. 25, 2006

(30) Foreign Application Priority Data
Jan. 26, 2004 (JP) 2004-016704

(51) Int. Cl. H01L 33/00

(52) U.S. Cl. 257/95

(57) ABSTRACT

A light receiving module M comprises a photodiode 1, an IC chip 2, a light permeable and electrically insulating sealing resin member 4 for sealing the photodiode 1 and the IC chip 2, a lens 43 provided at a surface of the sealing resin member 4 facing the photodiode 1, and a light impermeable and conductive coating5 for covering the sealing resin member 4 with the lens 43 being exposed. The coating 5 is connected to the ground and is made of a conductive resin, while being formed with a vertical wall 51 surrounding the lens 43.

### TECHNICAL FIELD

The present invention relates to a light receiving module such as an infrared receiving module used for receiving infrared rays transmitted from e.g. an infrared ray transmitter.

### BACKGROUND ART

FIG. 8 is an overall perspective view illustrating an example of a conventional infrared receiving module (see Patent document 1 listed below). The illustrated infrared receiving module 9 is incorporated in an electrical appliance or other units, and receives infrared rays transmitted from an infrared ray transmitter (not shown) for remote control. The infrared receiving module 9 includes a sealing resin member 90 provided with a lens 90a. The sealing resin member 90 seals a photodiode and an IC chip (both not shown). The infrared rays transmitted from the infrared ray transmitter (not shown) are collected through the lens 90a and then received by the photodiode.

Patent document 1: JP-A-H07-273356.

The outside of the sealing resin member 90 is provided with a conductive layer 91 made of metal foil. A plurality of terminals 92a-92c are electrically connected to the photodiode and the IC chip, and protrude out of the sealing resin member 90. The conductive layer 91 is connected to the terminal 92a serving as a ground terminal. Thus, the conductive layer 91 serves as an electromagnetic shield, so that the IC chip is prevented from malfunctioning due to the electromagnetic noise coming from outside.

A part of the conductive layer is formed to be a mesh on the surface of the lens 90a. Due to the meshed portion 91a of the conductive layer 91 on the surface of the lens 90a, the infrared rays transmitted from the infrared ray transmitter is not entirely blocked, while the electromagnetic noise is prevented from entering into the infrared receiving module 9 through the lens 90a.

However, in the above-described infrared receiving module 9, the lens 90a is partly covered by the meshed portion 91a of the conductive layer 91. Thus, the infrared rays transmitted from the infrared ray transmitter are partly blocked by the meshed portion 91a, thereby reducing the amount of infrared rays arriving at the photodiode through the lens 90a. As a result, in the conventional infrared receiving module 9, the sensitivity to infrared rays is decreased.

In the conventional module structure, if the meshed portion 91a were not formed on the lens 90a, the sensitivity to infrared rays would not deteriorate. In such a case, however, the shielding function at the lens 90a would be impaired.

### DISCLOSURE OF THE INVENTION

The present invention has been proposed under the above-described circumstances. It is therefore an object of the present invention to provide a light receiving module that does not suffer deterioration of the electromagnetic shielding function, and enjoys good light sensitivity.

A light receiving module according to the present invention comprises a light receiving element, an IC chip, a light permeable and electrically insulating sealing member for sealing the light receiving element and the IC chip, a lens provided at a surface of the sealing member facing the light receiving element, and a light impermeable and electroconductive coating for covering the sealing member with the lens exposed. The coating is connected to ground and is provided with a vertical wall that is made up of a conductive member and arranged to surround the lens.

In this structure, the vertical wall of the coating efficiently blocks electromagnetic noise toward the lens from the peripheral portion of the lens. Thus, differing from the conventional device, there is no need to form a meshed portion for electromagnetic shielding at a part of the lens, as a means of preventing the IC chip from malfunctioning due to the electromagnetic noise. In the structure, the entire or substantially entire surface of the lens is widely exposed, so that a great amount of light passes through the lens and reaches the light receiving element. As a result, in the present invention, the light sensitivity can be improved without decreasing the electromagnetic shielding function.

Further, since the coating is formed of an electroconductive resin, the coating may be easily made using a mold. In comparison with the conventional conductive layer made of a metal foil, the coating can be formed easily, thereby reducing the product cost. Especially, according to the present invention, the vertical wall, which is difficult to be formed of a metal foil, can be formed easily.

Preferably, the lens may be a convex lens. The vertical wall may have a height greater than the height of the lens in the thickness direction of the lens.

Due to the structure, the electromagnetic noise traveling toward the lens from the peripheral portion of the lens can be reliably blocked by the vertical wall, thereby improving the electromagnetic shielding function.

Preferably, the vertical wall may include an inner surface capable of light reflection. The inner surface may be inclined in a manner such that an inner diameter of the vertical wall is reduced as proceeding toward a bottom of the wall.

Due to the structure, a desired amount of light can be collected into the lens by utilizing the inner surface. Thus, the amount of the light entering into the lens can be increased, whereby the light sensitivity is much improved.

Preferably, the sealing member and the conductive member may be formed of a resin. Due to the structure, the sealing member and the conductive member can be easily made.

### BRIEF DESCRIPTION OF THE DRAWINGS

FIG. 1 is a perspective view illustrating an infrared receiving module according to an embodiment of the present invention.

FIG. 2 is a longitudinal sectional view taken along lines II-II of FIG. 1.

FIG. 3 is a lateral sectional view taken along lines I-I of FIG. 1.

FIG. 4 is a sectional view showing the principal portion of the light receiving module of FIG. 1, for illustrating the manufacture process of the same.

FIG. 5 is a sectional view of the principal portion of the infrared receiving module, illustrating a modified example of a vertical wall of a coating.

FIG. 6 is a sectional view of the principal portion of the infrared receiving module, illustrating another modified example of the vertical wall of the coating.

FIG. 7 is a lateral sectional view illustrating other embodiment of the infrared receiving module according to the present invention.

FIG. 8 is an overall perspective view illustrating an example of a conventional infrared receiving module.

### BEST MODE FOR CARRYING OUT THE INVENTION

Preferred embodiments of the present invention will be described below with reference to the accompanying drawings.

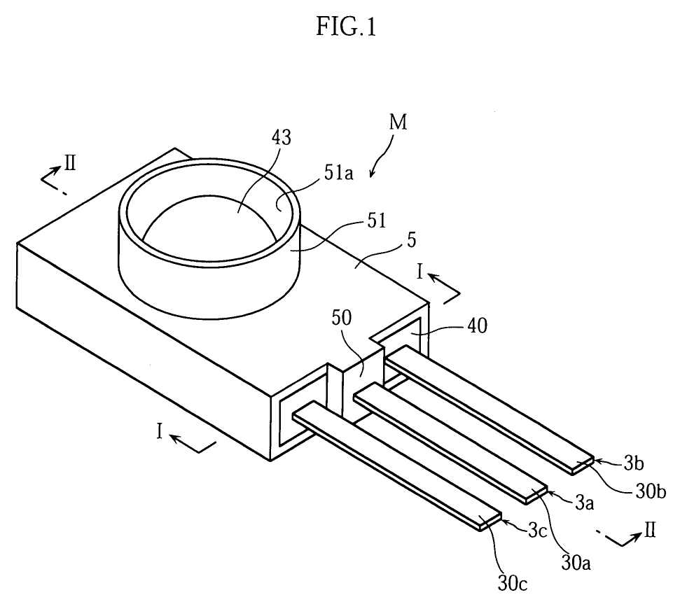

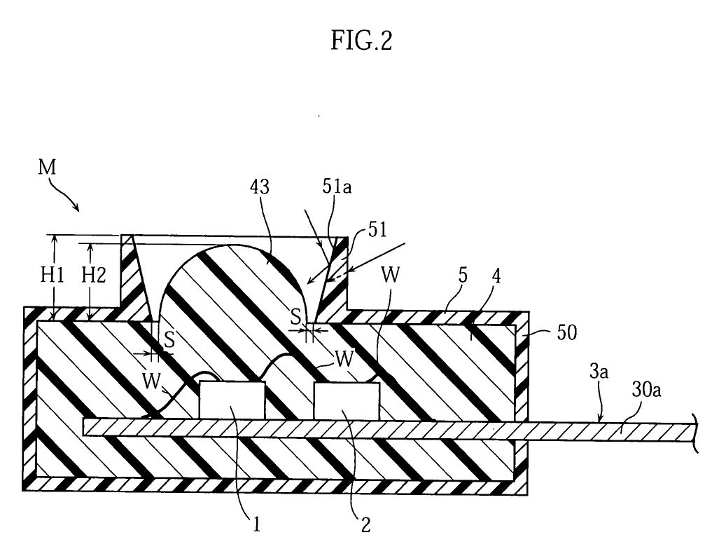

FIGS. 1-3 illustrate an infrared receiving module according to an embodiment of the present invention. The infrared receiving module M of this embodiment is incorporated in an electric appliance such as a television receiver, a videocassette player/recorder, an audiovisual apparatus, and an air conditioner, and receives infrared rays emitted from an infrared ray transmitter for remote controlling. As shown in FIGS. 1 and 2, the infrared receiving module M includes a photodiode 1 serving as a light receiving element, an IC chip 2, first to third leads 3a-3c, a sealing resin member 4, and a coating 5.

The photodiode 1 receives infrared rays transmitted by an infrared ray transmitter (not shown), and generates photovoltaic power corresponding to the infrared rays so as to generate electric current. The IC chip 2 is provided with a current/voltage converter circuit, an amplifier circuit, a limit circuit, and a detector circuit (neither of them shown), and converts the electric current generated at the photodiode 1 into an output signal to be sent to a predetermined external control unit.

The first to third leads 3a-3c support and electrically connect the photodiode 1 and the IC chip 2, and are made of a metal such as copper and nickel. Each of the first to third leads 3a-3c is divided into an inner portion covered by the sealing resin member 4 and an outer portion projecting outwardly from a base end surface 40 of the sealing resin member 4. The outer portions of the first to third leads 3a-3c provide a ground terminal 30a, a power supply voltage terminal 30b, and an output terminal 30c, respectively.

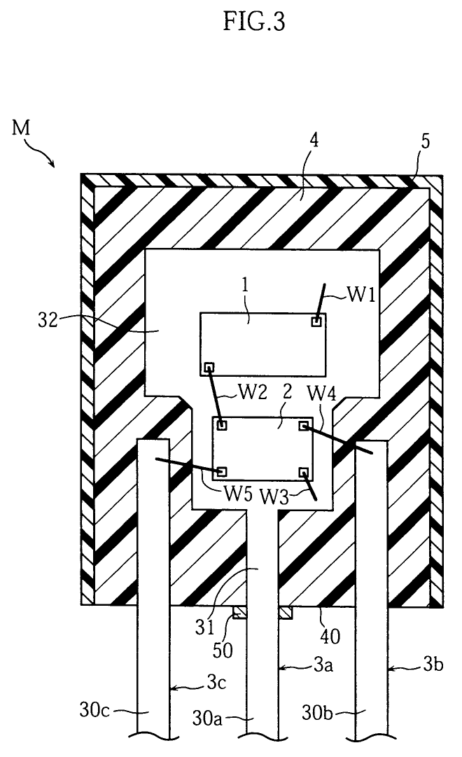

As shown in FIG. 3, the inner portion of the first lead 3a includes a connecting portion 31 connected to the ground terminal 30a, and a mounting portion 32 that is connected to the connecting portion 31 and provides a plan surface on which the photodiode land the IC chip 2 are mounted. On the mounting portion 32, the IC chip 2 and the photodiode 1 are mounted in the mentioned order on a line extending from the connecting portion 31.

The negative terminal of the photodiode 1 is connected to the mounting portion 32 (serving as a ground electrode) via a wire W1, while the positive terminal is connected to the IC chip via a wire W2. The ground terminal of the IC chip 2 is connected to the mounting portion 32 via a wire W3 while the other two terminals are respectively connected to the inner portions of the second lead 3b and the third lead 3c via wires W4, W5.

The sealing resin member 4 hermetically covers the photodiode 1 and the IC chip 2, and this resin member may be made of e.g. epoxy resin containing a pigment for shielding visible light. The sealing resin member 4 is visible-light-impermeable but infrared-permeable. The sealing resin member 4 is substantially rectangular parallelepiped, and the top surface of the sealing resin member 4 is provided with a substantially hemispheric convex lens 43 at a portion facing the photodiode 1. The lens 43 collects infrared rays traveling from outside into the photodiode 1 for efficient receiving of the infrared rays.

The coating 5 is made of a conductive resin material, e.g. epoxy resin containing conductive fillers such as carbon. The coating 5 is impermeable to both of visible light and infrared rays. The coating 5 is formed to partly cover the surface of the sealing resin member 4, except the base end surface 40 and the lens 43. The base end surface 40 is partly formed with a connecting portion 50 contacting the ground terminal 30a in conduction therewith, whereby the coating 5 is grounded.

The coating 5 includes a substantially cylindrical vertical wall 51 surrounding the lens 43. The vertical wall 51 has a height H1 which is equal to or greater than a height H2 of the lens 43. In view of reducing the overall thickness of the infrared receiving module, it is favorable to equalize the heights H1, H2.

The vertical wall 51 includes an inner circumferential surface 51a inclined in a manner such that its inner diameter becomes smaller as proceeding toward the bottom of the vertical wall 51. This linearly inclined surface may be replaced with a downwardly curved surface. The inner circumferential surface 51a is formed to be highly infrared reflective. This can be easily achieved by using a white or nearly white conductive resin to form the coating 5. Alternatively, the inner circumferential surface 51 may be laminated with an infrared reflective layer.

A gap S is provided between the lowermost portion of the inner circumferential surface 51a and the outer circumferential edge of the lens 43. Though the gap S is not indispensable for ensuring the function of the module, its existence facilitates manufacture of a mold for forming the coating 5, as described below.

In manufacturing the above-described infrared receiving module M, the sealing resin member 4 and the coating 5 are formed of a resin with the use of a mold.

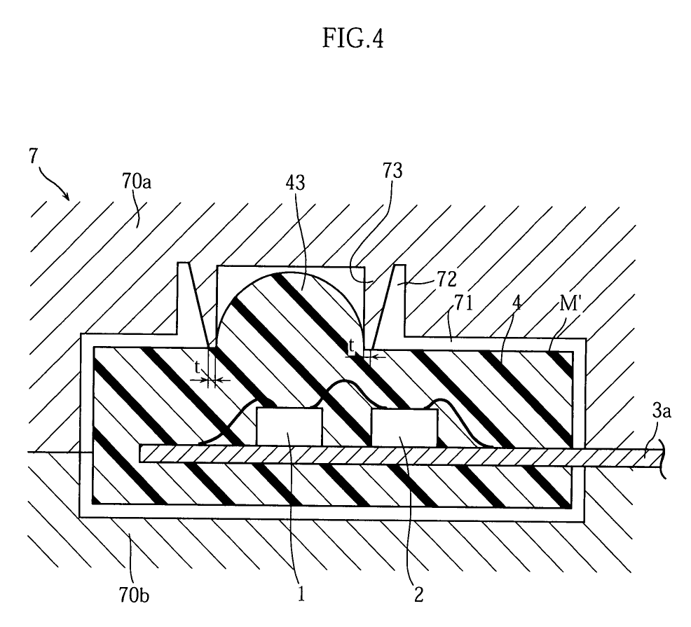

Specifically, as shown in FIG. 4, an intermediate product M′ is prepared, which includes a sealing resin member 4 but not a coating 5, and then the intermediate product M′ is placed in a cavity 71 formed by an upper portion 70a and a lower portion 70b of a mold 7. Next, a melted conductive resin is supplied into the cavity 71 to form the coating 5. The upper portion 70a has a recess 72 for forming the vertical wall 51 and a projection 73 for separating the recess 72 and the lens 43 of the intermediate product M′.

As described above with reference to FIG. 2, a gap S is provided between the lowermost portion of the vertical wall 51 and the outer circumferential edge of the lens 43. In this manner, the thickness t of the end of the projection 73 is equalized to the width of the gap S, and the wall of the projection 73 can have a sufficient thickness. As a result, the projection 73 has a proper mechanical strength. Further, in molding the coating 5, the end of the projection 73 is brought into surface contact with the top surface of the sealing resin member 4, and this configuration ensures hermetical contact between them. Consequently, it is possible to prevent the conductive resin supplied into the cavity 71 from flowing to and touching the lens 43.

In the infrared receiving module M, the coating 5 serves as an electromagnetic shield, and so does the vertical wall 51. Therefore, electromagnetic noise traveling toward the lens 43 from around the lens 43 (except the upper side) is shielded by the vertical wall 51, and thus the electromagnetic noise is prevented from entering into the sealing resin member 4 from the lens 43. The vertical wall 51 is taller than the lens 43 and entirely surrounds the lens 43, so as to improve the above-described electromagnetic shielding function. Thus, malfunction due to electromagnetic noise can be prevented.

The coating 5 is impermeable to both of visible light and infrared rays, so that disturbing external light is prevented from entering into the sealing resin member 4 from a portion other than the lens 43. Thus, an error at the IC chip 2 due to the disturbing external light can also be prevented.

The surface of the lens 43 is not covered by the coating 5, and thus light incident area of infrared rays at the lens 43 is large in comparison with the conventional infrared receiving module 9 shown in FIG. 8. Therefore, differently from the conventional infrared receiving module 9, the amount of infrared rays arriving at the photodiode 1 is not reduced due to the meshed portion 91a of the conductive layer 91.

Some of the infrared rays traveling from the upper side of the lens 43 arrive at the inner circumferential surface 51a of the vertical wall 51 and are reflected by the inner circumferential surface 51a, so that the infrared rays may be guided to the lens 43. Specifically, as the inner circumferential wall 51a is flared from the base end toward the tip end of the vertical wall 51, and thus the inner diameter of the tip end of the vertical wall 51 is larger than the lens 43, the amount of infrared rays entering into the lens 43 is the sum of the infrared rays entering directly and the infrared rays entering through the above-described reflection. Thus, the amount of infrared rays received by the photodiode 1 is larger than the infrared rays received in the conventional infrared receiving module 9, thereby improving the sensitivity to infrared rays.

As described above, the coating 5 is made of a conductive resin and can be easily formed using a mold, and the vertical wall 51 can also be formed properly. Thus, the product cost of the entire infrared receiving module M can be reduced.

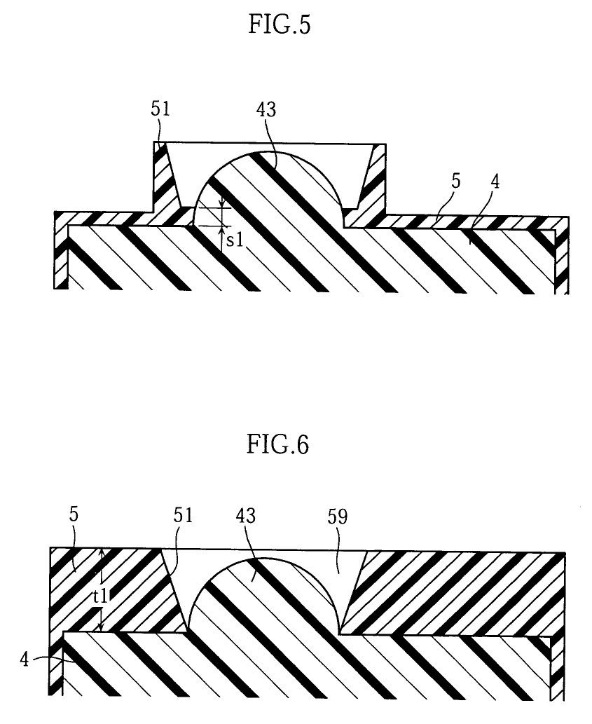

FIG. 5 illustrates another embodiment of the infrared receiving module. Specifically, the figure is a sectional view of the principal part of the infrared receiving module, showing a modification of the vertical wall of the coating.

In the vertical wall 51 of the coating 5 shown in FIG. 2, the gap S is provided between the lowermost portion of the inner circumferential surface 51a of the vertical wall 51 and the outer circumferential end of the lens 43, and the entire spherical surface of the lens 43 is exposed. However, not so large amount of infrared rays are reflected by the inner circumferential surface 51a of the vertical wall 51 to enter from the base end of the lens 43 (the bottom of the spherical surface), thus, even if the gap S is omitted and the coating 5 covers the bottom circumferential surface of the lens 43, the amount of the infrared rays to be received does not change so much.

The vertical wall 51 of the coating 5 shown in FIG. 5 is designed based on the above-described concept. Specifically, the coating 5 partly contacts the bottom circumferential surface of the lens 43 at a proper width sl, so that the coating 5 covers the base end of the lens 43. In this structure, the surface of the lens 43 can also be exposed at an area larger than in the conventional infrared receiving module 9, thereby improving the sensitivity to infrared rays.

FIG. 6 illustrates another modification of the vertical wall of the coating. Differently from the ones shown in FIGS. 2 and 5, in which the vertical wall 51 projects by a height corresponding to the lens 43 on the top surface of the sealing resin member 4, the example shown in FIG. 6 is provided with a coating 5 having a uniform thickness t1 over the top surface of the sealing resin member 4, where the thickness t1 is equal to or slightly greater than the height of the lens 43, and a portion of the coating corresponding in position to the lens 43 is formed with a recess 59 to expose the lens 43. The recess 59 provides a vertical wall 51.

The inner circumferential surface of the recess 59 is inclined. Similarly to the example shown in FIGS. 2 and 5, infrared rays are reflected by this inclined surface and then enter the lens 43. In the example shown in FIG. 6, a gap may also be provided between the base end of the lens 43 and the coating 5.

In the example shown in FIG. 6, the overall shape of the infrared receiving module is of a rectangular column, and this configuration prevents the vertical wall 51 from being damaged. In view of reducing the total volume of the coating 5 for overall downsizing, however, it may be favorable that the vertical wall is formed into a cylindrical projection as shown in FIGS. 2 and 5.

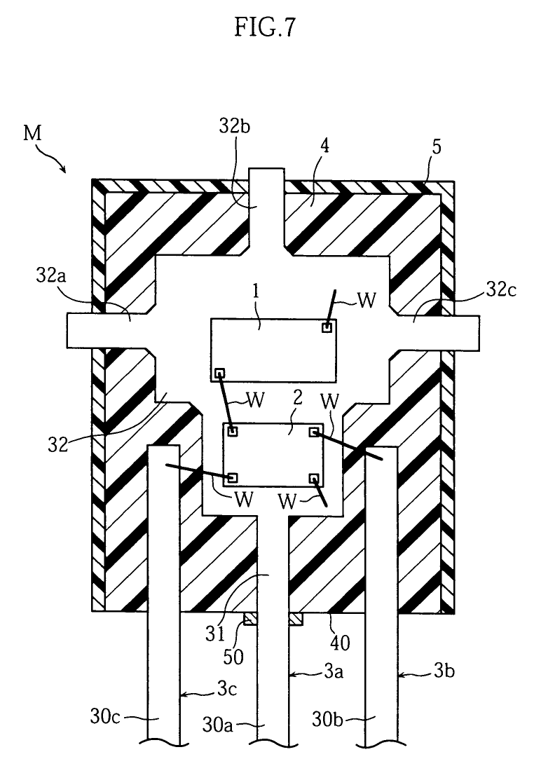

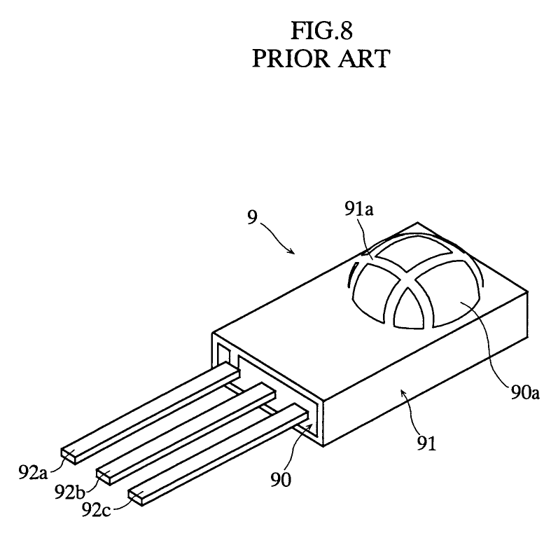

FIG. 7 illustrates another embodiment of the infrared receiving module. This figure is a sectional view of the principal part of the infrared receiving module, showing a modified grounding arrangement for the mounting portion 32 connected to the inner portion of the first lead 3a.

The infrared receiving module M shown in the figure is provided with a first connecting portion 32a and a second connecting portion 32c extending to and beyond the coating 5 from the side ends of the mounting portion 32 of the inner portion of the first lead 3a shown in FIG. 3, and provided with a third connecting portion 32d extending to and beyond the coating 5 from the front end of the mounting portion 32. The tips of the first to third connecting portions 32a-32c are respectively connected to the coating 5, so that the mounting portion 32 is grounded at the front end and the side ends.

Due to the above structure, the ground terminal 30a is electrically connected to the connecting portion 50 of the coating 5 and further, the first to third connecting portions 32a-32c are electrically connected to the coating 5. Thus, if noise is generated at the circuits of the photodiode 1 and the IC chip 2, it can be discharged to the ground by as short a distance as possible, thereby enhancing the noise shielding function. In the infrared receiving module shown in FIG. 7, the tip ends of the first to third connecting portions 32a-32c are exposed outside. However, this is not limitative, and the tip ends of the first to third connecting portions 32a-32c may come into contact with the inner surface of the coating 5 for electrical conduction.

The present invention is not limited to the above-described embodiments, and the structure of the light receiving module according to the present invention may be variously modified. For example, the vertical wall 51 is not limited to the circular cylindrical projection, but may be a tubular projection (e.g. polygonal tube).

The photodiode 1 and the IC chip 2 may be integrally formed as a one-chip. The light receiving element is not limited to the photodiode, but may be a phototransistor.

The present invention may also be applied to a light receiving module capable of detecting light of other wavelengths than that of infrared light. Further, the light receiving module of the invention has at least a light receiving function, and may further be provided with a light emitting function in addition to the light receiving function. Thus, the scope of the present invention may include a light receiving/emitting module having a function for emitting infrared ray or light of other wavelengths, and an optical communication module.

1. A light receiving module comprising: a light receiving element, an IC chip, a light permeable and electrically insulating sealing member for sealing the light receiving element and the IC chip, a lens provided at a surface of the sealing member facing the light receiving element, and a light impermeable and electroconductive coating for covering the sealing member with the lens exposed, the coating being connected to ground,
wherein the coating is provided with a vertical wall made up of an electroconductive member and surrounding the lens.

2. The light receiving module according to claim 1, wherein the lens is a convex lens,
wherein the vertical wall has a height greater than a height of the lens in a thickness direction of the lens.

3. The light receiving module according to claim 2, wherein the vertical wall includes an inner surface for reflecting light, the inner surface being inclined in a manner such that an inner diameter of the vertical wall is reduced as proceeding toward a bottom.

4. The light receiving module according to claim 1, wherein the sealing member and the electroconductive member are made of resin.
